(19) United States
(12) Patent Application Publication
(10) Pub. No.: US 2025/0228067 A1
(43) Pub. Date: Jul. 10, 2025

(54) QUANTUM DOT ELECTROLUMINESCENT DEVICE, METHOD OF PREPARING THE SAME AND DISPLAY DEVICE INCLUDING THE SAME

(71) Applicant: Najing Technology Corporation Limited, Hangzhou (CN)

(72) Inventor: Yuan GAO, Hangzhou (CN)

(73) Assignee: Najing Technology Corporation Limited, Hangzhou (CN)

(21) Appl. No.: 19/015,197

(22) Filed: Jan. 9, 2025

Related U.S. Application Data
(60) Provisional application No. 63/618,916, filed on Jan. 9, 2024.

(51) Int. Cl. H10K 50/165; H10K 50/115; H10K 50/18; H10K 71/13

(52) U.S. Cl. CPC H10K 50/165; H10K 50/115; H10K 50/181; H10K 71/135

(57) ABSTRACT

Provided is a quantum dot electroluminescent device, a method for preparing the same, and a display device including the same. The quantum dot electroluminescent device includes a substrate; a first electrode disposed on a surface on one side of the substrate; an electron transport layer disposed on a surface of the first electrode away from the substrate or disposed on the surface of the substrate, and the electron transport layer is an N-type semiconductor layer, the N-type semiconductor layer including GaN or GaₓAl₍₁₋ₓ₎N or AlₓGa_{y}In_{(1-x-y)}N, 0<x+y<1; a quantum dot light-emitting layer disposed on a surface of the electron transport layer away from the substrate; and a second electrode disposed on a surface of the quantum dot light-emitting layer away from the substrate. The quantum dot electroluminescent device has long life and high brightness.

### FIELD

The present disclosure relates to quantum dot electroluminescent emitting technology, more specifically, a quantum dot electroluminescent device, a method of preparing the same and a display device including the same.

### BACKGROUND

Light-emitting device is a device that converts electrical energy into light, such as organic light-emitting device with organic materials as light-emitting materials, quantum dot light-emitting device with quantum dots as light-emitting materials.

In the last decade, a new generation of quantum dot light-emitting diodes (QD-LED) rises, thanks to the past two or three decades of quantum dots synthesis technology advances, the luminous efficiency of the core-shell structure of the quantum dots can be as high as 100%; and quantum dot light-emitting spectrum is easy to adjust, as long as changing the size of the quantum dots or doped with other elements, its light-emitting wavelength can be adjusted in all the visible wavelengths and can be extended to the near-infrared band and near-ultraviolet band, greatly increasing the prospect of its development and utilization. In addition, the quantum dots have narrower full width at half maxima in the light-emitting spectrum, generally less than 30 nm, to meet an important requirement of LED for high-performance display device. Another important factor, the photochemical stability of quantum dots compared with organic materials has been significantly improved, can effectively extend the life of LED devices to meet commercial requirements. At the same time, quantum dot light-emitting diode can be produced through a full solution process in large area, greatly reducing the LED production costs.

However, the current quantum dot light-emitting diode technology generally uses zinc oxide nanocrystals as the electron transport material, still limiting the life of the QD-LED, and cannot reflect the theoretically achievable quantum dot light-emitting material's advantage of longer lifetime.

### SUMMARY

In view of the foregoing, we recognize that there is a need in the art to replace the nanocrystal-type electron transport material causing unstable performance of the quantum dot electroluminescent device.

In one aspect the present disclosure provides a quantum dot electroluminescent device, it includes a substrate; a first electrode, provided on a surface on one side of the substrate; an electron transport layer, provided on a surface of the first electrode away from the substrate or provided on a surface of the substrate, the electron transport layer being an N-type semiconductor layer, the N-type semiconductor layer including GaN or GaₓAl₍₁₋ₓ₎N or AlₓGa_{y}In_{(1-x-y)}N, where 0<x<1, 0<y<1, 0<x+y<1; a quantum dot light-emitting layer, provided on a surface of the electron transport layer away from the substrate; a second electrode, provided on a surface of the quantum dot light-emitting layer away from the substrate.

In another aspect, the present disclosure provides a method of preparing the foregoing quantum dot electroluminescent device, it includes: preparing the substrate and the first electrode; disposing the N-type semiconductor layer on the first electrode to obtain the electron transport layer; preparing the quantum dot light-emitting layer on the electron transport layer by a solution method or a photolithography method; and disposing the second electrode on the quantum dot light-emitting layer.

In still another aspect, the present disclosure provides a display device, it includes the quantum dot electroluminescent device described above.

### BRIEF DESCRIPTION OF DRAWINGS

The accompanying drawings of the specification, which form part of this disclosure, are used to provide a further understanding of the present disclosure, and the schematic embodiments of the disclosure and their illustrations are used to explain the present disclosure and do not constitute an undue limitation of the disclosure. In the accompanying drawings:

FIG. 1 shows a schematic structure of a quantum dot electroluminescent device of an embodiment.

FIG. 2 shows a schematic diagram of a structure of a quantum dot electroluminescent device of another embodiment.

FIG. 3 shows a schematic diagram of the structure of a quantum dot electroluminescent device of another embodiment.

FIG. 4 shows a schematic diagram of the structure of a quantum dot electroluminescent device of another embodiment.

FIG. 5 shows a schematic diagram of the structure of a quantum dot electroluminescent device of another embodiment.

FIG. 6 shows a schematic diagram of a structure of a quantum dot electroluminescent device of another embodiment.

Note that in the embodiments illustrated below, sometimes the same attachment mark is used in common between different accompanying drawings to indicate the same portion or portions having the same function, and the repetition of the description thereof is omitted. In some instances, similar markings and letters are used to denote similar items, so that once an item is defined in one of the accompanying drawings, no further discussion thereof is required in the subsequent accompanying drawings.

For ease of understanding, the positions, dimensions and ranges, etc., of the various structures shown in the accompanying drawings, etc., sometimes do not indicate actual positions, dimensions and ranges, etc. Accordingly, the present disclosure is not limited to the positions, dimensions and ranges, etc. disclosed in the accompanying drawings and the like.

### DESCRIPTION OF EMBODIMENTS

Various exemplary embodiments of the present disclosure will be described in detail below with reference to the accompanying drawings. It should be noted that the relative arrangements, numerical expressions, and values of the components and steps set forth in these embodiments do not limit the scope of the present disclosure unless otherwise specifically stated.

The following description of at least one exemplary embodiment is in fact merely illustrative and in no way serves as any limitation on the present disclosure and its application or use. That is, the structures and methods herein are shown in an exemplary manner to illustrate different embodiments of the structures and methods of the present disclosure. However, those skilled in the art will understand that they are merely illustrative of exemplary ways in which the present disclosure can be implemented and are not exhaustive. In addition, the accompanying drawings need not be drawn to scale, and some features may be enlarged to show details of specific components.

In addition, techniques, methods, and apparatus known to one of ordinary skill in the relevant field may not be discussed in detail, but where appropriate, said techniques, methods, and apparatus should be considered part of the authorized specification.

In all of the examples illustrated and discussed herein, any specific values should be interpreted as merely exemplary and not as limitations. Thus, other examples of exemplary embodiments may have different values.

The words “left”, “right”, “front”, “back” in the specification and claims, “top”, “bottom”, “up”, “down”, “high”, “low”, etc., if they exist, are used for descriptive purposes and not necessarily to describe unchanging relative positions. It should be understood that the words so used are interchangeable where appropriate, enabling the embodiments of the present disclosure described herein, for example, to operate in other orientations than those shown or otherwise described herein. For example, when the device in the accompanying drawings is inverted, features originally described as being “above” other features may be described as being “below” other features. The device may also be oriented in other ways (rotated 90 degrees or in other orientations), and the relative spatial relationships will be interpreted accordingly.

In the specification and in the claims, one element is said to be “on”, “attached” to, “connected” to, or “coupled” to another element, etc., the element may be directly on top of, directly attached to, directly connected to, directly coupled to another element, or one or more intermediate elements may be present. By contrast, an element is said to be “directly on” another element, “directly attached” to another element, “directly connected” to another element, “directly coupled” to another element, there will be no intermediate element. In the specification and claims, a feature arranged to be “adjacent” to another feature may mean that a feature has a portion that overlaps an adjacent feature or is located above or below an adjacent feature.

As used herein, the term “exemplary” means “used as an example, instance, or illustration” and not as a “model” to be precisely reproduced. Any of the implementations described herein exemplarily are not necessarily to be construed as preferred or advantageous over other implementations. Furthermore, the present disclosure is not limited by any expressed or implied theories given in the art, the background art, the content of the invention, or the specific embodiments.

As used herein, the term “about” is intended to encompass any small variation due to design or manufacturing defects, tolerances of the device or component, environmental influences, and/or other factors.

In addition, the terms “first,” “second,” and the like may be used herein for reference purposes only and are thus not intended to be limiting. For example, the words “first,” “second,” and other such numerical terms relating to structures or components do not imply order or sequence unless the context clearly indicates otherwise.

It should also be understood that the term “include/contain/comprise” as used herein indicates the presence of the indicated features, integrals, steps, operations, units, and/or components, but does not preclude the presence or addition of one or more other features, integrals, steps, operations, units, and/or components, and/or combinations thereof.

For the purposes of this disclosure, the term “providing” is used broadly to encompass all ways of obtaining an object, so that “providing an object” includes, but is not limited to, “purchasing”, “preparing/manufacturing”, “arranging/setting up”, “installing/assembling”, and/or “ordering” an object, etc. as used herein.

As used herein, the term “and/or” includes any and all combinations of one or more of the listed items in association. The terms used herein are for the purpose of describing particular embodiments only and are not intended to limit the present disclosure. As used herein, the singular forms “one,” “a,” and “the” are also intended to include the plural form unless the context clearly indicates otherwise.

According to a first aspect of the present disclosure, there is provided a quantum dot electroluminescent device including a substrate; a first electrode disposed on a surface on one side of the substrate; an electron transport layer disposed on a surface of the first electrode away from the substrate or disposed on said surface of the substrate, and the electron transport layer being an N-type semiconductor layer, the N-type semiconductor layer including GaN or GaₓAl₍₁₋ₓ₎N or AlₓGa_{y}In_{(1-x-y)}N, where 0<x<1, 0<y<1, 0<x+y<1; a quantum dot light-emitting layer disposed on the surface of the electron transport layer away from the substrate; a second electrode disposed on surface of the quantum dot light-emitting layer away from the substrate. For example, the GaN crystal is more stable in physicochemical properties compared to conventional zinc oxide nanocrystalline electron transport material. The GaN has a band gap of 3.4 eV which is larger than that of common blue light quantum dot materials, and is even larger than that of red and green quantum dot materials, and the position of the LUMO energy level of the GaN crystal is about 4.0 eV, which is close to that of zinc oxide, and is favorable for electron injection, and the position of the HOMO energy level of the GaN crystal is about 7.4 eV, which can effectively block holes. Therefore, the N-type semiconductor material as the electron transport material can well meet the requirements of the electron injection material, and the quantum dot electroluminescent device has the technical advantages of long life and high brightness. Adding different proportions of Al element or/and In element to GaN can effectively adjust its bandgap width and conduction band energy level position to better adapt to quantum dot materials and further enhance the performance of quantum dot electroluminescent device.

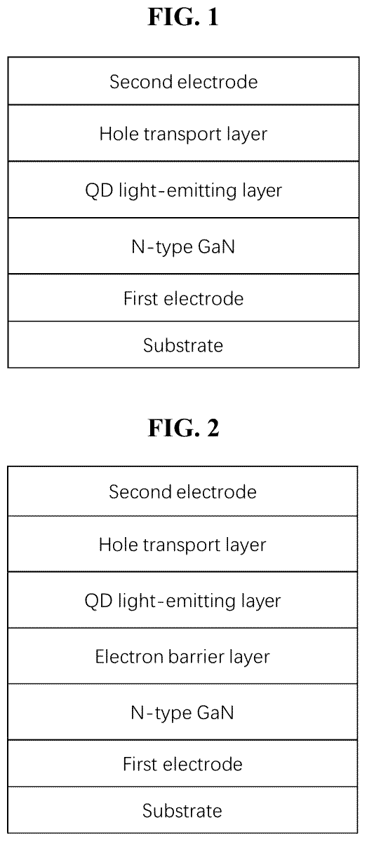

In some embodiments, when the electron transport layer is directly provided on the first electrode disposed on a surface on one side of the substrate, the quantum dot light-emitting layer is provided on a surface of the electron transport layer away from the substrate. Examples are shown in FIG. 1 to FIG. 4.

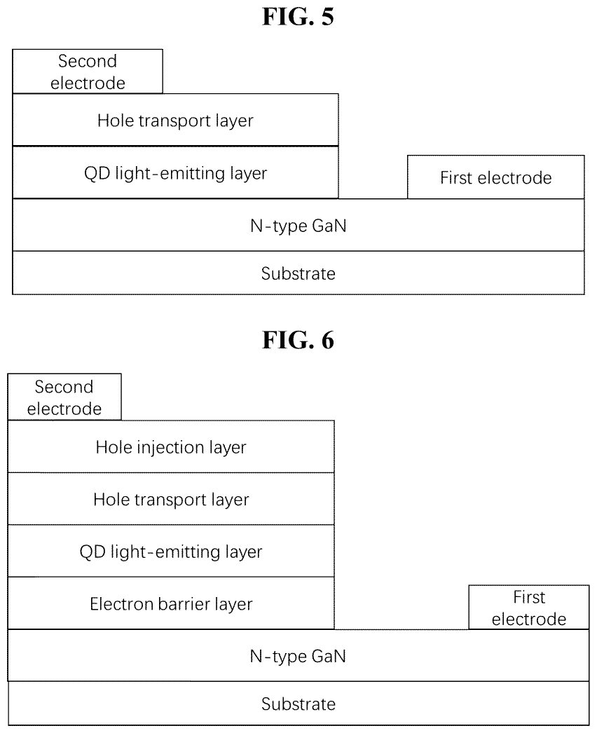

In some embodiments, when the electron transport layer is directly provided on the substrate, the quantum dot light-emitting layer is provided on a surface of the electron transport layer away from the substrate, and the first electrode is also provided on the surface of the electron transport layer away from the substrate. In some embodiments, the orthographic projection area of the quantum dot light-emitting layer on the substrate is larger than the orthographic projection area of said first electrode on the substrate. Examples are shown in FIG. 5 or FIG. 6. The orthographic projection area of the quantum dot light-emitting layer on the substrate is not overlapped with the orthographic projection area of said first electrode on the substrate.

In some embodiments, the thickness of the electron transport layer is 10 nm to 5000 nm, or 10 nm to 15000 nm. In some embodiments, the thickness of the electron transport layer is 20 nm to 3000 nm, 20 nm to 4000 nm, 20 nm to 3000 nm, 20 nm to 2000 nm, 20 nm to 1000 nm, 500 nm to 1000 nm, 500 nm to 2000 nm, 500 nm to 3000 nm, 500 nm to 4000 nm, or 500 nm to 5000 nm.

In some embodiments, a doping element of the N-type semiconductor layer is Si or Ge, and a doping concentration is 1×10¹⁵ cm⁻³ to 1×10²¹ cm⁻³. The electron mobility can be adjusted by the adjustment of the doping concentration, which facilitates the selection of other matching device materials accordingly. The doping concentration may be 1×10¹⁵ cm⁻³ to 1×10²⁰ cm⁻³, 1×10¹⁵ cm⁻³ to 1×10¹⁹ cm⁻³, 1×10¹⁵ cm⁻³ to 1×10¹⁸ cm⁻³, 1×10¹⁵ cm⁻³ to 1×10¹⁷ cm⁻³, or 1×10¹⁵ cm⁻³ to 1×10¹⁶ cm⁻³.

In some embodiments, the quantum dot electroluminescent device further includes a hole transport layer, the hole transport layer being disposed between the second electrode and the quantum dot light-emitting layer. In some embodiments, the hole transport material is selected from (N-carbazolyl)-1,1′-biphenyl (CBP), 1,3-bis(N-carbazolyl)benzene (MCP), N,N′-diphenyl-N,N′-(1-naphthalenyl)-1,1′-biphenyl-4,4′-diamine (NPB), N,N′-bis(naphthalen-1-yl)-N,N′-bis(phenyl)-2,7-diamino-9,9-spirobifluorene (Spiro-NPB), 4,4′-cyclohexylbis[N,N-bis(4-methylphenyl)aniline] (TAPC), 4,4′,4″-tri-9-carbazolyltriphenylamine (TCTA), poly(9,9-dioctylfluorene-alt-N-(4-butylphenyl)diphenylamine) (TFB), poly((9,9-dioctylfluorenyl-2,7-diyl)-alt-(9-(2-ethylhexyl)-carbazole-3,6-diyl)) (PF8CZ), or poly[N,N′-bis(4-butylphenyl)-N,N′-bis(phenyl)benzidine] (POLY-TPD). The thickness of the hole transport layer may range from 10 nm to 500 nm.

In some embodiments, the quantum dot electroluminescent device further includes a hole injection layer, the hole injection layer being disposed between the second electrode and the quantum dot light-emitting layer. In some embodiments, the hole injection material is selected from dipyrazino[2,3-f:2′,3′-h]quinoxaline-2,3,6,7,10,11-hexacarbonitrile (HAT-CN) or MoO₃. The thickness of the hole injection layer may range from 5 nm to 50 nm.

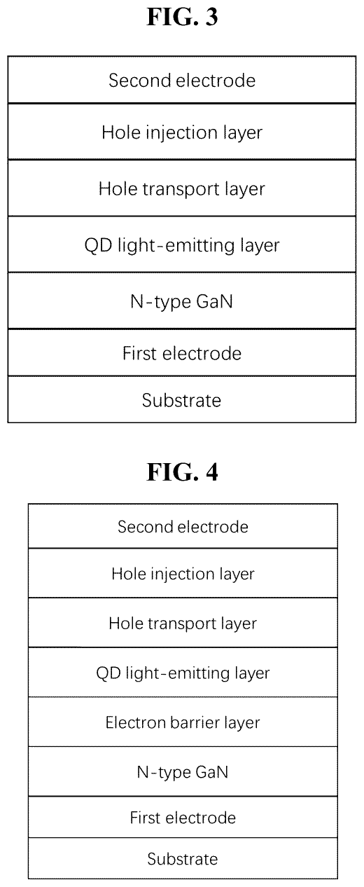

In some embodiments, the quantum dot light-emitting layer and the second electrode may have a multilayer structure between them, which includes a hole injection layer/hole transport layer structure, a hole injection layer/hole transport layer/luminescence-assisting layer structure, a hole injection layer/luminescence-assisting layer structure, a hole transport layer/luminescence-assisting layer structure, or a hole injection layer/hole transport layer/hole-blocking layer structure. In each structure, the layers are sequentially stacked on the second electrode according to the described order. In some embodiments, the structure of the quantum dot electroluminescent device is shown in FIG. 3.

In some embodiments, the quantum dot electroluminescent device further includes an electron blocking layer, the electron blocking layer being disposed between the electron transport layer and the quantum dot light-emitting layer. In some embodiments, a thickness of the electron blocking layer is 1 nm to 100 nm.

In some embodiments, the electron blocking layer is a GaN layer, an Al₂O₃ layer, a SiO₂ layer, or an AlN layer. When an excess of electrons is injected into the electron transport layer, a certain thickness of intrinsic crystalline GaN (undoped), Al₂O₃, SiO₂, or AlN can continue to be grown on the N-type doped semiconductor layer to act as a barrier for the electrons.

In some embodiments, the quantum dot light-emitting layer includes at least one type of quantum dot. The core of the quantum dot may be selected from group II-VI compound, group III-VI compound, group I-III-VI compound, group III-V compound, group III-II-V compound, group IV-VI compound, group IV element, group IV compound, and combinations thereof. The full width at half maximum (FWHM) of the emission peak of the fluorescence emission spectrum of the quantum dots may be less than or equal to about 45 nm, or less than or equal to about 40 nm, or less than or equal to about 30 nm. In some embodiments, the quantum dot light-emitting layer may include one or more layers.

In some embodiments, the quantum dot electroluminescent device may also include other functional layers between the layers described above.

In some embodiments, the quantum dot electroluminescent device includes one or more light-emitting units. The plurality of light-emitting units, for example, includes red, green, and blue color emitting units.

In some embodiments, the first electrode material is selected from one or more of Au, Ag, Al, Cu, and Si. In some embodiments, the first electrode has a thickness of 20 nm to 1000 nm, preferably 50 nm to 200 nm. The first electrode can be one or more layers.

In some embodiments, the second electrode material is selected from lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or combinations thereof, and the second electrode may be a single layer or multiple layers. In some embodiments, the second electrode has a thickness of 10 nm to 1000 nm, preferably 20 nm to 150 nm. When the second electrode is a light exiting electrode, it is necessary to control its thickness in a range having a high light transmittance.

In some embodiments, the quantum dot electroluminescent device includes a pixel array, such as including a plurality of red, green, and blue sub-pixels.

According to a second aspect of the present disclosure, there is provided a method of preparing the quantum dot electroluminescent device described above, including: preparing the substrate and the first electrode; disposing the N-type semiconductor layer on the first electrode to obtain the electron transport layer; preparing the quantum dot light-emitting layer on the electron transport layer by a solution method or a photolithography method; and disposing the second electrode on the quantum dot light-emitting layer. In the above preparation method, since the material of the electron transport layer is a stable material, the raw material of the quantum dot light-emitting layer, such as quantum dot ink or quantum dot adhesive, has a larger selectable formula, and the process of forming the quantum dot light-emitting layer is easier to realize.

The solution method means that quantum dots are prepared in a solution state for device preparation. The photolithography method means that the quantum dot light-emitting layer can be patterned using a mask under lighting condition. Photolithography allows for higher resolution of the quantum dot electroluminescent device.

In some embodiments, the N-type semiconductor layer is prepared in situ. The preparation method of the N-type semiconductor layer may be MOCVD.

In some embodiments, the N-type semiconductor layer is prepared non-in situ, the specific method including: preparing the N-type semiconductor layer, bonding the N-type semiconductor layer and the first electrode to obtain the electron transport layer. In some embodiments, the bonding method is a thermal bonding. In some embodiments, process of preparing the N-type semiconductor layer includes, epitaxially growing the N-type semiconductor layer on another substrate and then stripping to obtain the N-type semiconductor layer. The other substrate may be sapphire, silicon carbide or silicon nitride, etc. The stripping method may be a laser method.

In some embodiments, the substrate is a substrate containing a thin film transistor or a driver circuit. In some embodiments, the substrate includes a sapphire, silicon carbide, or silicon nitride layer. In some embodiments, the substrate is a substrate with a pixel isolation structure. In some embodiments, preparing the substrate and the first electrode may optionally include directly outsourcing a part in which the first electrode and the substrate are already bonded, or it may include procuring the substrate and then disposing the first electrode on that substrate and then forming a bonded part.

In some embodiments, the quantum dot electroluminescent device includes one or more light-emitting units. At least one light-emitting unit is prepared according to the method described above.

In some embodiments, the first electrode and the second electrode may be prepared independently by using the method of vaporization or sputtering.

In some embodiments, the solution method is one of inkjet printing, spin coating, or spraying.

In some embodiments, the preparation method further includes providing a hole transport layer, the hole transport layer being disposed between the second electrode and the quantum dot light-emitting layer.

In some embodiments, the method of preparation further includes providing a hole injection layer, the hole injection layer being disposed between the second electrode and the quantum dot light-emitting layer.

In some embodiments, the hole transport layer or the hole injection layer may be prepared by, for example, inkjet printing, deposition, sputtering, or coating.

In some embodiments, the preparation method further includes providing an electron blocking layer, the electron blocking layer being disposed between the electron transport layer and the quantum dot light-emitting layer.

In some embodiments, the electron blocking layer is a GaN layer, an Al₂O₃ layer, a SiO₂ layer, or an AlN layer. When an excess of electrons is injected into the electron transport layer, a certain thickness of intrinsic crystalline GaN (undoped), Al₂O₃, SiO₂, or AlN can continue to be grown on the N-type doped semiconductor layer to serve as a barrier to the electrons.

In some embodiments, the preparation method may further include disposing other functional layers, between the layers described above. In some embodiments, the other functional layers may be prepared by, for example, inkjet printing, deposition, sputtering, or coating.

According to a third aspect of the present disclosure, there is provided a method of preparing the quantum dot electroluminescent device described above, including: preparing the substrate; disposing said N-type semiconductor layer on the substrate; disposing the first electrode on a first region of the N-type semiconductor layer; preparing the quantum dot light-emitting layer on a second region of the N-type semiconductor layer by a solution method or a photolithography method; and disposing a second electrode on the quantum dot light-emitting layer.

In some embodiments, the first region and the second region are not overlapped.

In some embodiments, the solution method is one of inkjet printing, spin coating or spraying.

In some embodiments, the preparation method further includes providing a hole transport layer, the hole transport layer being disposed between the second electrode and the quantum dot light-emitting layer.

In some embodiments, the method of preparation further includes providing a hole injection layer, the hole injection layer being disposed between the second electrode and the quantum dot light-emitting layer.

In some embodiments, the hole transport layer or the hole injection layer may be prepared by, for example, inkjet printing, deposition, sputtering, or coating.

In some embodiments, the preparation method further includes disposing an electron blocking layer, the electron blocking layer being disposed between the electron transport layer and the quantum dot light-emitting layer.

In some embodiments, the electron blocking layer is a GaN layer, an Al₂O₃ layer, a SiO₂ layer, or an AlN layer. When an excess of electrons is injected into the electron transport layer, a certain thickness of intrinsic crystalline GaN (undoped), Al₂O₃, SiO₂, or AlN can continue to be grown on the N-type doped semiconductor layer to serve as a barrier for the electrons.

In some embodiments, the preparation method may further include disposing other functional layers, disposed between the layers described above. In some embodiments, the other functional layers may be prepared by, for example, inkjet printing, deposition, sputtering, or coating.

In some embodiments, the method of preparing the N-type semiconductor layer may be MOCVD. In some embodiments, the methods of preparing the first electrode and the second electrode may independently be vaporization or sputtering.

According to a fourth aspect of the present disclosure, there is provided a display device, the display device including the quantum dot electroluminescent device described above. The display device having the above-described device structure has the technical advantages of long life and high brightness.

Although some particular embodiments of the present disclosure have been described in detail by way of examples, it should be understood by those skilled in the art that the above examples are for illustrative purposes only and are not intended to limit the scope of the present disclosure. The embodiments disclosed herein may be combined in any combination without departing from the spirit and scope of the present disclosure. It should also be understood by those skilled in the art that multiple modifications can be made to the embodiments without departing from the scope and spirit of the present disclosure. The scope of the present disclosure is limited by the appended claims.

What is claimed is:

1. A quantum dot electroluminescent device, comprising:
a substrate;
a first electrode, provided on a surface on one side of the substrate;
an electron transport layer, provided on a surface of the first electrode away from the substrate or provided on a surface of the substrate, the electron transport layer being an N-type semiconductor layer, the N-type semiconductor layer comprising GaN or GaₓAl₍₁₋ₓ₎N or AlₓGa_{y}In_{(1-x-y)}N, wherein 0<x<1, 0<y<1, 0<x+y<1;
a quantum dot light-emitting layer, provided on a surface of the electron transport layer away from the substrate;
a second electrode, provided on a surface of the quantum dot light-emitting layer away from the substrate.

2. The quantum dot electroluminescent device according to claim 1, wherein the electron transport layer has a thickness of 10 nm to 15000 nm.

3. The quantum dot electroluminescent device according to claim 1, wherein a doping element of the N-type semiconductor layer is Si or Ge, and a doping concentration is 1×10¹⁵ cm⁻³ to 1×10²¹ cm⁻³.

4. The quantum dot electroluminescent device according to claim 1, wherein the quantum dot electroluminescent device further comprising a hole transport layer, the hole transport layer being disposed between the second electrode and the quantum dot light-emitting layer.

5. The quantum dot electroluminescent device according to claim 1, wherein the quantum dot electroluminescent device further comprising a hole injection layer, the hole injection layer being disposed between the second electrode and the quantum dot light-emitting layer.

6. The quantum dot electroluminescent device according to claim 1, wherein the quantum dot electroluminescent device further comprising an electron blocking layer, the electron blocking layer being disposed between the electron transport layer and the quantum dot light-emitting layer.

7. The quantum dot electroluminescent device according to claim 6, wherein the electron blocking layer is a GaN layer, an Al₂O₃ layer, a SiO₂ layer, or an AlN layer.

8. A method of preparing the quantum dot electroluminescent device according to claim 1, comprising:
preparing the substrate and the first electrode;
disposing the N-type semiconductor layer on the first electrode to obtain the electron transport layer;
preparing the quantum dot light-emitting layer on the electron transport layer by a solution method or a photolithography method; and
disposing the second electrode on the quantum dot light-emitting layer.

9. The method of preparing the quantum dot electroluminescent device according to claim 8, wherein preparing the N-type semiconductor layer, and bonding the N-type semiconductor layer and the first electrode to obtain the electron transport layer.

10. The method of preparing the quantum dot electroluminescent device according to claim 8, wherein the solution method is one of inkjet printing, spin coating or spraying.

11. The method of preparing the quantum dot electroluminescent device according to claim 9, wherein a method of preparing the N-type semiconductor layer comprising: epitaxially growing an N-type semiconductor layer on another substrate and then stripping to obtain the N-type semiconductor layer.

12. The method of preparing the quantum dot electroluminescent device according to claim 8, wherein the method further comprising: providing a hole transport layer, the hole transport layer being disposed between the second electrode and the quantum dot light-emitting layer.

13. The method of preparing the quantum dot electroluminescent device according to claim 8, wherein the method further comprising: providing a hole injection layer, the hole injection layer being disposed between the second electrode and the quantum dot light-emitting layer.

14. The method of preparing the quantum dot electroluminescent device according to claim 12, wherein the hole transport layer being prepared by inkjet printing, deposition, sputtering, or coating.

15. The method of preparing the quantum dot electroluminescent device according to claim 13, wherein the hole injection layer being prepared by inkjet printing, deposition, sputtering, or coating.

16. The method of preparing the quantum dot electroluminescent device according to claim 8, wherein the method further comprising: providing an electron blocking layer, the electron blocking layer being disposed between the electron transport layer and the quantum dot light-emitting layer.

17. The method of preparing the quantum dot electroluminescent device according to claim 16, wherein the electron blocking layer is a GaN layer, an Al₂O₃ layer, a SiO₂ layer, or an AlN layer.

18. A display device, comprising the quantum dot electroluminescent device according to claim 1.
